(19) United States
(12) Patent Application Publication
(10) Pub. No.: US 2022/0209383 A1
(43) Pub. Date: Jun. 30, 2022

(54) PRINTED CIRCUIT BOARD TRANSMISSION LINE UTILIZED AS MILLIMETER WAVE ATTENUATOR

(71) Applicant: UNIVERSAL SCIENTIFIC INDUSTRIAL ( SHANGHAI ) CO., LTD., SHANGHAI (CN)

(72) Inventor: KUAN-HSING LI, SHANGHAI (CN)

(21) Appl. No.: 17/243,754

(22) Filed: Apr. 29, 2021

(30) Foreign Application Priority Data
Dec. 30, 2020 (CN) 202011607622.2

(51) Int. Cl. H01P 1/22; H05K 1/02

(52) U.S. Cl. CPC H01P 1/227; H05K 1/0237

(57) ABSTRACT

A printed circuit board transmission line utilized as a millimeter wave attenuator is provided. The printed circuit board transmission line includes a transmission line and a signal feed part. The transmission line has a first terminal and a second terminal. The signal feed part is electrically connected to the first terminal. The transmission line has a predetermined line width and a predetermined line length. The signal feed part receives an external signal, and the external signal is outputted from the second terminal through the transmission line. According to a degree of signal loss required in a practical application, the signal loss of the transmission line can be between 3 decibels and 40 decibels through a cooperation of the predetermined line width and the predetermined line length. Further, when the transmission line is utilized as a millimeter wave termination, the signal loss of the transmission line is 20 decibels.

### CROSS-REFERENCE TO RELATED PATENT APPLICATION This application claims the benefit of priority to China Patent Application No. 202011607622.2, filed on Dec. 30, 2020 in People's Republic of China. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE The present disclosure relates to a printed circuit board transmission line, and more particularly to a printed circuit board transmission line suitable for being utilized as a millimeter wave frequency band attenuator.

### BACKGROUND OF THE DISCLOSURE Currently, a 50 ohm chip resistor is commonly used as an attenuator or a termination for a signal in frequency bands ranging from 704 MHz to 960 MHz and from 2.4 GHz to 5 GHz. The termination can also be called a terminal resistor. The termination is a device that is matched with a characteristic impedance of a transmission line at a terminal of the transmission line, so as to prevent a reflection of the signal at the terminal of the transmission line.

For a millimeter wave of a higher frequency band (ranging from 26.5 GHz to 29.5 GHz), a wavelength of the signal is very short when a frequency of the signal is extremely high. When the shortened wavelength is comparable to a length of the transmission line, a reflected signal at the terminal of the transmission line is superimposed on the signal, and a shape of a signal waveform is accordingly changed. If the characteristic impedance of the transmission line is not matched with (or is not equal to) a load impedance of the termination, the reflection occurs at a load terminal.

Since the millimeter wave has an extremely high frequency, the reflection of the signal occurs if the chip resistor is connected to the terminal of a millimeter wave transmission line. Accordingly, the conventional 50 ohm chip resistor is not suitable for being utilized as the termination at the terminal of the millimeter wave transmission line, since an ideal matching effect cannot be achieved.

Therefore, how to overcome the above-mentioned inadequacy through improving the structural design has become one of the important issues to be solved in the field.

### SUMMARY OF THE DISCLOSURE In response to the above-referenced technical inadequacy, the present disclosure provides a printed circuit board transmission line utilized as a millimeter wave attenuator, which includes a transmission line and a signal feed part. The transmission line includes a first terminal and a second terminal. The signal feed part is electrically connected to the first terminal. The transmission line has a predetermined line width and a predetermined line length. The signal feed part receives an external signal, and the external signal is outputted from the second terminal through the transmission line. According to a requirement for a signal isolation at two terminals of a line in a practical application, a signal loss of the transmission line can be between 3 decibels (dB) and 40 decibels (dB) through a cooperation of the predetermined line width and the predetermined line length of the transmission line, so that the transmission line is capable of being utilized as the millimeter wave attenuator. Further, when the transmission line is utilized as a millimeter wave termination, the signal loss of the transmission line can be 20 decibels (dB) by adjusting the predetermined line width and the predetermined line length.

In certain embodiments, the printed circuit board transmission line includes a second signal feed part, which is electrically connected to the second terminal.

In certain embodiments, the second terminal is an open circuit termination. In certain embodiments, the second terminal is a ground terminal. In certain embodiments, the transmission line has a spiral structure. In certain embodiments, the transmission line has a characteristic impedance of 50 ohms.

In certain embodiments, the transmission line has a characteristic impedance of 80 ohms.

In certain embodiments, the signal feed part has a characteristic impedance of 50 ohms.

In certain embodiments, the printed circuit board transmission line utilized as the millimeter wave attenuator further includes a quarter-wavelength transformer, which is connected between the signal feed part and the first terminal.

In another aspect, the present disclosure provides a printed circuit board transmission line utilized as a millimeter wave attenuator, which includes a transmission line and a plurality of signal feed parts. The transmission line includes two transmission line main bodies. The two transmission line main bodies are cross-connected. Each of the two transmission line main bodies includes a first terminal and a second terminal. Each of the plurality of signal feed parts is electrically connected to one of the first terminal or one of the second terminals, correspondingly. The transmission line has a predetermined line width and a predetermined line length. One of the plurality of signal feed parts receives an external signal, and the external signal is outputted from another one of the plurality of signal feed parts through the transmission line main bodies. According to a requirement for a signal isolation at two terminals of a line required in a particular application, a signal loss of the transmission line can be between 3 decibels (dB) and 40 decibels (dB) through a cooperation of the predetermined line width and the predetermined line length of the transmission line, so that the transmission line is capable of being utilized as the millimeter wave attenuator. Further, when the transmission line is utilized as a millimeter wave termination, the signal loss of the transmission line can be 20 decibels (dB) by adjusting the predetermined line width and the predetermined line length.

In certain embodiments, a part of each of the two transmission line main bodies near corresponding one of the plurality of signal feed parts has a hairpin structure.

Therefore, in the printed circuit board transmission line utilized as the millimeter wave attenuator provided by the present disclosure, the transmission line can be equivalent to a resistor and achieve a matching effect for functioning as the millimeter wave attenuator by virtue of “the signal loss of the transmission line being between 3 decibels and 40 decibels through the cooperation of the predetermined line width and the predetermined line length” and by a physical characteristic of having a higher loss when the transmission line has a longer path.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic perspective view of a printed circuit board transmission line according to a first embodiment of the present disclosure;

FIG. 2 is a schematic view of a predetermined line length and a predetermined line width of the printed circuit board transmission line of the present disclosure;

FIG. 3 is another schematic perspective view of the printed circuit board transmission line according to the first embodiment of the present disclosure;

FIG. 4 is still another schematic perspective view of the printed circuit board transmission line according to the first embodiment of the present disclosure;

FIG. 5 is a schematic perspective view of a printed circuit board transmission line according to a second embodiment of the present disclosure;

and

FIG. 6 is a schematic perspective view of a printed circuit board transmission line according to a third embodiment of the present disclosure.

### DETAILED DESCRIPTION OF THE EXEMPLARY EMBODIMENTS The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

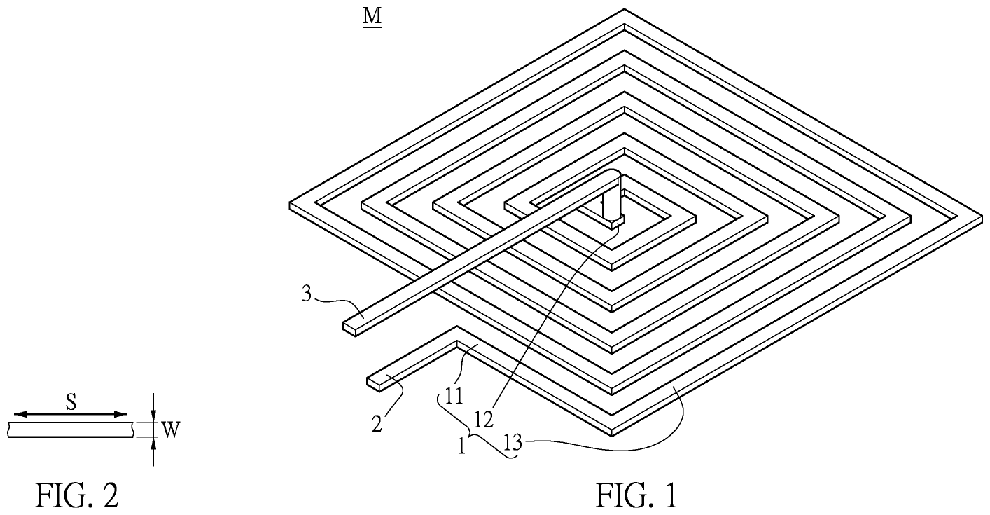

Referring to FIG. 1 and FIG. 2, a first embodiment of the present disclosure provides a printed circuit board transmission line M, which includes a transmission line 1 and a signal feed part 2. The transmission line 1 has a first terminal 11 and a second terminal 12, and the signal feed part 2 is electrically connected to the first terminal 11. As shown in FIG. 2, the transmission line 1 has a predetermined line width W and a predetermined line length S, and the predetermined line width W and the predetermined line length S can be adjusted according to practical requirements of a user. The signal feed part 2 receives an external signal from an external signal source. The external signal enters the transmission line 1 through the first terminal 11, and the external signal is outputted from the second terminal 12 after a transmission through the transmission line 1. It should be noted that through a cooperation of the predetermined line width W and the predetermined line length S of the transmission line 1, a signal loss (also called an insertion loss) of the transmission line 1 is between 3 decibels (dB) and 40 decibels (dB). In another embodiment, through the cooperation of the predetermined line width W and the predetermined line length S of the transmission line 1, the signal loss (also called the insertion loss) of the transmission line 1 can be 20 decibels (dB).

Furthermore, the transmission line 1 as shown in FIG. 1 further includes a second signal feed part 3, and the second signal feed part 3 is electrically connected to the second terminal 12. At this time, the transmission line 1 is utilized as a millimeter wave attenuator. According to a requirement for a signal isolation at two terminals of a line in a practical application, the signal loss of the transmission line 1 can be between 3 decibels (dB) and 40 decibels (dB) through the cooperation of the predetermined line width W and the predetermined line length S of the transmission line 1, so that the transmission line 1 can be utilized as the millimeter wave attenuator.

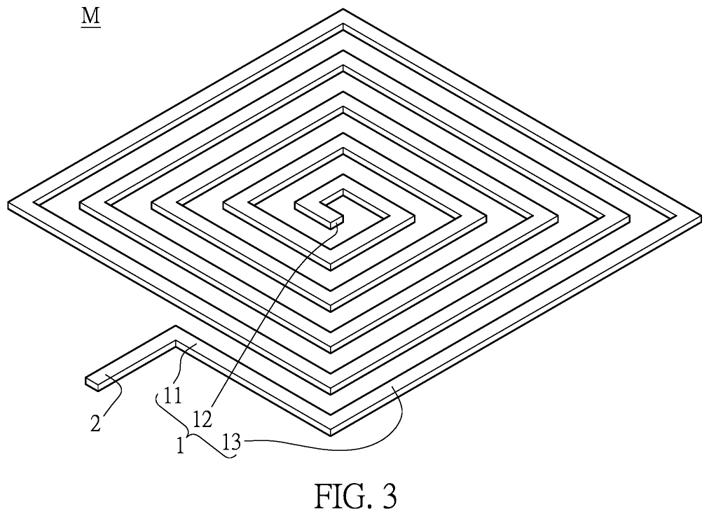

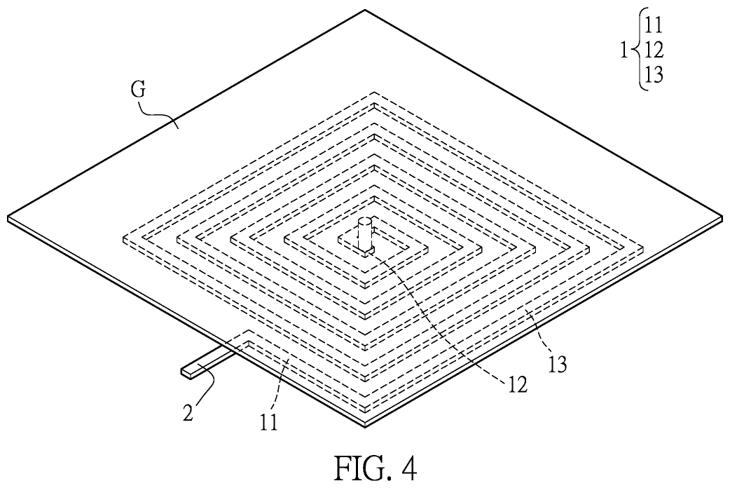

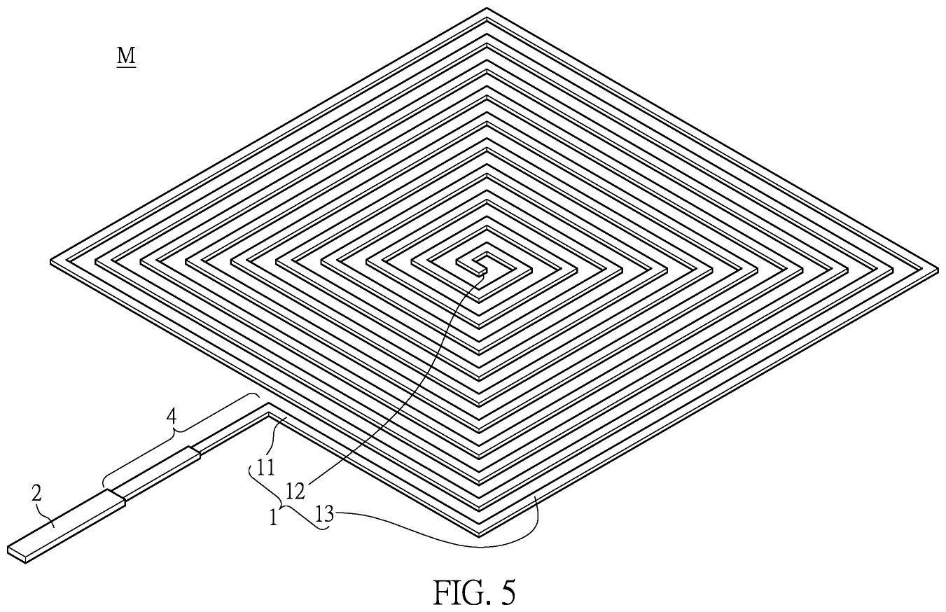

It is worth mentioning that the printed circuit board transmission line M of the present disclosure refers to a wiring structure of the printed circuit board transmission line, so that the first terminal 11 and the second terminal 12 can be arranged on different layers of a printed circuit board, and do not need to be arranged on the same plane. However, the present disclosure is not limited thereto. In another embodiment, the second terminal 12 of the transmission line 1 does not need to be connected to another signal feed part; instead, an open circuit termination or a ground terminal is formed at the second terminal 12 of the transmission line 1. As shown in FIG. 3 and FIG. 4, the second terminal 12 of the transmission line 1 in FIG. 3 is the open circuit termination, and the second terminal 12 of the transmission line 1 in FIG. 4 is directly grounded to a ground G to form the ground terminal. For the second terminal 12 that is the open circuit termination or the ground terminal, the transmission line 1 at this time is utilized as a millimeter wave termination. It should be noted that, the termination is in fact a kind of attenuator, and a difference lies only in whether or not the two terminals of the transmission line 1 are used for signal transmission, or whether or not one of the two terminals of the transmission line 1 is the open circuit termination or the ground terminal.

The same effect can be achieved by the second terminal 12 that is the open circuit termination or the ground terminal, since each of an open circuit and a short circuit to ground in a radio frequency signal transmission causes a total reflection. Accordingly, as long as a path length (i.e., the predetermined line length S) of the transmission line 1 is long enough, a return loss of 20 decibels (dB), which is equivalent to a conventional terminal resistor, can also be achieved after the total reflection.

Further, the return loss of 20 decibels (dB) signifies that a reflected power of the signal is 1% of an incident power of the signal. In other words, the reflected power of the signal is extremely small compared to the incident power of the signal, which results in an excellent matching effect. In the present disclosure, the printed circuit board transmission line M replaces a chip resistor to serve as the termination, so that the signal loss of the transmission line 1 equals to the return loss generated when the transmission line 1 is utilized as the termination. That is, in the present disclosure, the return loss of 20 decibels (dB) can be achieved by having the printed circuit board transmission line M replace the chip resistor to serve as the termination.

As mentioned above, the path length (i.e., the predetermined line length S) of the transmission line 1 needs to be long enough, and also needs to meet an area limitation in the printed circuit board. Accordingly, the transmission line 1 is wired in a manner by which a specific shape is formed through winding. For example, as shown in FIG. 1, FIG. 3 and FIG. 4, the transmission line 1 has a spiral structure. Moreover, in addition to having the first terminal 11 and the second terminal 12, the transmission line 1 further has a winding main body 13 that is connected between the first terminal 11 and the second terminal 12. In the present embodiment, the winding main body 13 has the spiral structure. The first terminal 11 is arranged at an outmost periphery of the winding main body 13, and the second terminal 12 is arranged at a center of the winding main body 13.

### Second Embodiment

Referring to FIG. 5, a second embodiment of the present disclosure provides a printed circuit board transmission line M, which also includes the transmission line 1 and the signal feed part 2. The transmission line 1 has the first terminal 11, the second terminal 12, and the winding main body 13 that is connected between the first terminal 11 and the second terminal 12. The winding main body 13 has the spiral structure as described in the first embodiment. The second terminal 12 of the transmission line 1 in FIG. 5 is used as the open circuit termination; therefore, the transmission line 1 in FIG. 5 is utilized as the termination. A difference between the second embodiment and the first embodiment is that the predetermined length width W of the transmission line 1 in the second embodiment is narrower than the predetermined length width W of the transmission line 1 in the first embodiment. Accordingly, for printed circuit boards having the same winding area, the winding main body 13 of the transmission line 1 in the second embodiment has more turns. That is, the predetermined line length S of the transmission line 1 in the second embodiment is longer than the predetermined line length S of the transmission line 1 in the first embodiment.

Since the predetermined length width W of the transmission line 1 in the second embodiment is narrower than the predetermined length width W of the transmission line 1 in the first embodiment, the transmission line 1 in the second embodiment and the transmission line 1 in the first embodiment have different characteristic impedances. For example, the transmission line 1 in the first embodiment can have a characteristic impedance of 50 ohms, while the transmission line 1 in the second embodiment can have a characteristic impedance of 80 ohms. It is worth mentioning that the signal feed part 2 and the transmission line 1 do not necessarily have the same characteristic impedance. Accordingly, in the present embodiment, when the transmission line 1 has the characteristic impedance of 80 ohm, the signal feed part 2 can have the characteristic impedance of 50 ohm. Under such circumstance, the printed circuit board transmission line M can further include a quarter-wavelength transformer 4. The quarter-wavelength transformer is an impedance-matching component used to connect to a middle section where an input impedance is not matched with an output impedance. In the present embodiment, the quarter-wavelength transformer 4 is electrically connected between the signal feed part 2 and the first terminal 11 of the transmission line 1. The signal feed part 2 is matched with the transmission line 1 through a connection of the quarter-wavelength transformer 4, so as to reduce a loss of energy reflection during the signal transmission.

### Third Embodiment

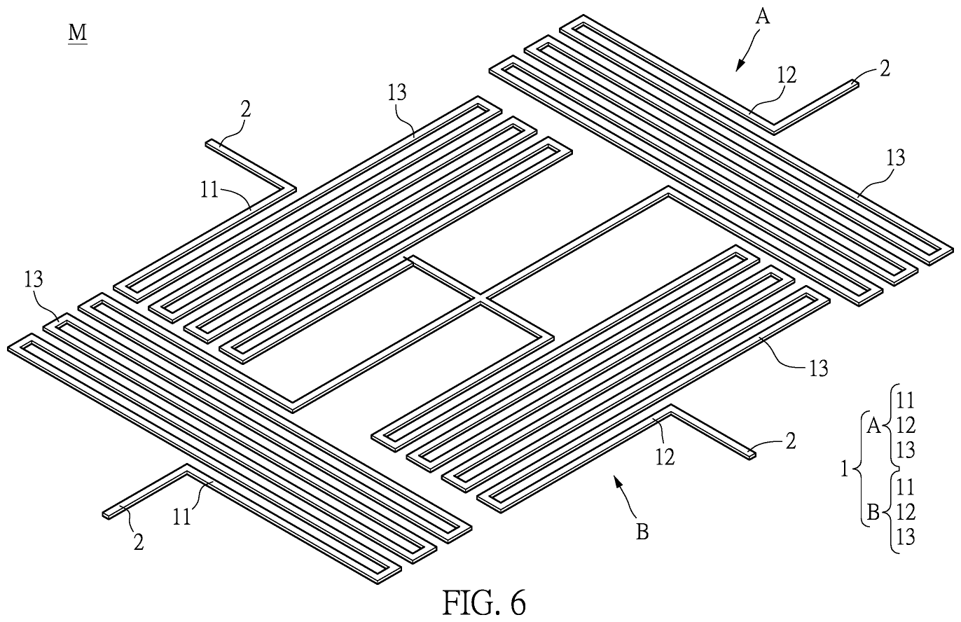

Referring to FIG. 6, the printed circuit board transmission line M of the present embodiment includes the transmission line 1 and a plurality of the signal feed parts 2. The transmission line 1 has two transmission line main bodies A, B, and the two transmission line main bodies A, B are cross-connected. Each of the two transmission line main bodies A, B has the first terminal 11, the second terminal 12 and the winding main bodies 13 connected between the first terminal 11 and the second terminal 12. Each of the signal feed parts 2 is electrically connected to one of the two first terminals 11 or one of the two second terminals 12, correspondingly. The transmission line 1 has the predetermined line width W and the predetermined line length S. One of the signal feed parts 2 receives the external signal from the external signal source, and through the transmission line main bodies A, B, the external signal is outputted from another one of the signal feed parts 2. Each of the first terminals 11 and the second terminals 12 of the transmission line 1 in FIG. 6 is used as a signal feed, so that the transmission line 1 in FIG. 6 is utilized as the attenuator. The signal loss of the transmission line 1 or the isolation between any two of the signal feed parts 2 can be between 3 decibels (dB) and 40 decibels (dB) through the cooperation of the predetermined line width W and the predetermined line length S of the transmission line 1.

Main differences between the third embodiment and the first embodiment and the second embodiment include the shape of the transmission line 1 and a quantity of the signal feed parts 2. In the present embodiment, the quantity of the signal feed parts 2 is four. The transmission line 1 has the two transmission line main bodies A, B that are cross-connected. A part of each of the two transmission line main bodies A, B near a corresponding one of the signal feed parts 2 has a hairpin structure. As shown in FIG. 6, each of the two transmission line main bodies A, B has two of the winding main bodies 13, and the winding main bodies 13 each have a hairpin structure.

Since the transmission line main body A and the transmission line main body B are cross-connected, in the present embodiment, the signal transmission is not limited to the transmission between the first terminal 11 of the transmission line main body A and the second terminal 12 of the transmission line main body A, or between the first terminal 11 of the transmission line main body B and the second terminal 12 of the transmission line main body B. For example, the first terminal 11 of the transmission line main body A can transmit the signal with the first terminal 11 of the transmission line main body B or the second terminal 12 of the transmission line main body B, and the second terminal 12 of the transmission line main body A can also transmit the signal with the first terminal 11 of the transmission line main body B or the second terminal 12 of the transmission line main body B.

### Beneficial Effects of the Embodiments

In conclusion, one of the beneficial effects of the present disclosure is that, in the printed circuit board transmission line utilized as the millimeter wave attenuator provided by the present disclosure, the transmission line 1 can achieve a matching effect for functioning as the attenuator by virtue of “the signal loss of the transmission line 1 being between 3 decibels and 40 decibels through the cooperation of the predetermined line width and the predetermined line length” and by a physical characteristic of having a higher loss when the transmission line 1 has a longer path.

Further, a degree of the signal loss depends on the length and the characteristic impedance of the transmission line. The characteristic impedance of the transmission line is decided by the transmission line width, a dielectric thickness of a stack of the printed circuit board, a material property of the stack (e.g., a dielectric constant (Dk) and a dielectric loss (Df)), process parameters (such as surface roughness of a copper line layer on the printed circuit board), etc. In other words, adjusting the degree of the signal loss is not easy. Through the cooperation of the predetermined line width W and the predetermined line length S of the transmission line 1 (when the predetermined length S is 500 mm and the predetermined line width W is 45 μm), the printed circuit board transmission line utilized as the millimeter wave attenuator provided by the present disclosure has the signal loss (also called the insertion loss) of 20 decibels (dB).

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated.

Alternative embodiments will become apparent to those skilled in the art to which the present disclosure pertains without departing from its spirit and scope.

What is claimed is:

1. A printed circuit board transmission line utilized as a millimeter wave attenuator, comprising:
a transmission line including a first terminal and a second terminal;
and
a signal feed part electrically connected to the first terminal;
wherein the transmission line has a predetermined line width and a predetermined line length; wherein the signal feed part receives an external signal, and the external signal is outputted from the second terminal through the transmission line; wherein, through a cooperation of the predetermined line width and the predetermined line length of the transmission line, a signal loss of the transmission line is between 3 decibels and 40 decibels.

2. The printed circuit board transmission line according to claim 1, further comprising:
a second signal feed part electrically connected to the second terminal.

3. The printed circuit board transmission line according to claim 1, wherein the second terminal is an open circuit termination.

4. The printed circuit board transmission line according to claim 1, wherein the second terminal is a ground terminal.

5. The printed circuit board transmission line according to claim 1, wherein the transmission line has a spiral structure.

6. The printed circuit board transmission line according to claim 1, wherein the transmission line has a characteristic impedance of 50 ohms.

7. The printed circuit board transmission line according to claim 1, wherein the transmission line has a characteristic impedance of 80 ohms.

8. The printed circuit board transmission line according to claim 7, wherein the signal feed part has a characteristic impedance of 50 ohms.

9. The printed circuit board transmission line according to claim 8, further comprising:
a quarter-wavelength transformer electrically connected between the signal feed part and the first terminal.

10. A printed circuit board transmission line utilized as a millimeter wave attenuator, comprising:
a transmission line including two transmission line main bodies, the two transmission line main bodies being cross-connected, and each of the two transmission line main bodies including a first terminal and a second terminal; and
a plurality of signal feed parts, each of the plurality of signal feed parts being electrically connected to a corresponding one of the first terminals or a corresponding one of the second terminals;
wherein the transmission line has a predetermined line width and a predetermined line length;
wherein one of the plurality of signal feed parts receives an external signal, and the external signal is outputted from another one of the plurality of signal feed parts through the transmission line main bodies; wherein, through a cooperation of the predetermined line width and the predetermined line length of the transmission line, a signal loss of the transmission line is between 3 decibels and 40 decibels.

11. The printed circuit board transmission line according to claim 10, wherein a part of each of the two transmission line main bodies that is near a corresponding one of the plurality of signal feed parts has a hairpin structure.
